(19) United States
(12) Patent Application Publication
(10) Pub. No.: US 2008/0285438 A1
(43) Pub. Date: Nov. 20, 2008

(54) METHODS, SYSTEMS, AND COMPUTER PROGRAM PRODUCTS FOR PROVIDING FAULT-TOLERANT SERVICE INTERACTION AND MEDIATION FUNCTION IN A COMMUNICATIONS NETWORK

(76) Inventors: Rohini Marathe, Cary, NC (US); Venkatararnaiah Ravishankar, Cary, NC (US); Raghavendra G. Rao, Cary, NC (US)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/106,869

(22) Filed: Apr. 21, 2008

Related U.S. Application Data
(60) Provisional application No. 60/925,612, filed on Apr. 20, 2007.
(60) Provisional application No. 60/991,260, filed on Nov. 30, 2007.
(60) Provisional application No. 60/992,384, filed on Dec. 5, 2007.

(51) Int. Cl. G01R 31/08

(52) U.S. Cl. 370/220

(57) ABSTRACT

Methods, systems, and computer program products for providing fault-tolerant service interaction and mediation function in a communications network are disclosed. According to one aspect, the subject matter described herein includes a method for providing fault-tolerant service interaction and mediation capability. The method includes providing an active instance of a service capability interaction manager (SCIM) function for providing service interaction and mediation between entities that request network services and entities that provide network services in a communications network. The method also includes providing a standby instance of the SCIM function. The active instance of the SCIM function performs service interaction and mediation between the entities that request network services and the entities that provide network services. In response to failure of the active SCIM function, the standby instance of the SCIM function takes over the service interaction and mediation previously performed by the active instance of the SCIM function.

### PRIORITY CLAIM

The application claims the benefit of U.S. Provisional Patent Application Ser. No. 60/925,612, filed Apr. 20, 2007, U.S. Provisional Patent Application Ser. No. 60/991,260, filed Nov. 30, 2007, and U.S. Provisional Patent Application Ser. No. 60/992,384, filed Dec. 5, 2007; the disclosures of which are incorporated herein by reference in their entireties.

### TECHNICAL FIELD

The subject matter described herein relates to providing services in mixed-protocol telecommunications networks. More particularly, the subject matter described herein relates to methods, systems, and computer program products for providing fault-tolerant service interaction and mediation instances in a communications network.

### BACKGROUND

As formerly separate and distinct networks merge, it is desirable that formerly incompatible network elements in the merged network interoperate with each other, often requiring what is herein referred to as service interaction and mediation. Service interaction refers to the process of managing interactions between network entities that request and use network services, commonly referred to as service clients, and network entities that provide network services, commonly referred to as application servers. Service mediation refers to the conversion of messages from one message protocol into another message protocol.

A functional entity that performs service interaction and mediation in a communications network is described in the 3^{rd} Generation Partnership Project (3GPP) specification TS 23.002, ETSI TS 123 002 V7.1.0 (2006-03). This document describes a service capability interaction manager (SCIM) for performing service interaction and mediation. The SCIM is designed to operate as an intermediary between service clients and application servers, such that the SCIM presents itself as an application server to a service client, and as a service client to an application server, while at the same time converting messages from the protocol used by the service client to the protocol used by the application server, and vice versa.

For example, the use of a SCIM may allow a mobile switching center (MSC) that uses an intelligent network (IN) protocol to communicate to a service control point (SCP) that uses a customized applications for mobile networks enhanced logic (CAMEL) protocol, thereby avoiding the expensive alternatives of upgrading either the MSC or SCP to speak the other's protocol. In this scenario, the MSC may direct all service requests to the SCIM, which appears to the MSC to be an SCP. The SCIM may convert the message from the MSC's protocol to the SCP's protocol and forward the message to the SCP. Similarly, the SCP may direct all service request responses to the SCIM, which appears to the SCP to be an MSC. The SCIM may convert the response from the SCP's protocol to the MSC's protocol and forward the response to the MSC.

One disadvantage to using a single entity to perform a function is that failure of that entity can dramatically affect or impair operation of the communications network. This is particularly true in the case of a service capability interaction manager, which may act as the sole interface between service clients and application servers in a communications network. Should the service capability interaction manager fail or otherwise be removed from operation, communication between service clients and application servers may cease. This may result in an inability of subscribers to use certain services of the network or even gain access to the network. Thus, there is a need to provide a fault-tolerant service capability interaction manager. Accordingly, there exists a need for methods, systems, and computer program products for providing fault-tolerant service interaction and mediation function in a communications network.

### SUMMARY

As used herein, the term “network element” refers to a logical grouping of entities that perform a specific assigned function or group of functions within a communications network.

According to one aspect, the subject matter described herein includes a method for providing fault-tolerant service interaction and mediation capability. The method includes providing an active instance of a service capability interaction manager (SCIM) function for providing service interaction and mediation between entities that request network services and entities that provide network services in a communications network. The method also includes providing a standby instance of the SCIM function. The active instance of the SCIM function performs service interaction and mediation between the entities that request network services and the entities that provide network services. In response to failure of the active SCIM function, the standby instance of the SCIM function takes over the service interaction and mediation previously performed by the active instance of the SCIM function.

According to another aspect, the subject matter described herein includes a fault-tolerant service interaction and mediation system. The system includes a first network element including an active instance of a service capability interaction manager (SCIM) function for providing service interaction and mediation between entities that request network services and entities that provide network services in a communications network. The system also includes a second network element including a standby instance of the SCIM function for, in response to failure of the active instance of the SCIM function, taking over the service interaction and mediation previously performed by the active instance of the SCIM function.

According to another aspect, the subject matter described herein includes a fault-tolerant service interaction and mediation network element. The network element includes an active instance of a service capability interaction manager (SCIM) function for providing service interaction and mediation between entities that request network services and entities that provide network services in a communications network. The network element also includes a standby instance of the SCIM function for, in response to failure of the active instance of the SCIM function, taking over the service interaction and mediation previously performed by the active instance of the SCIM function. The active and standby instances of the SCIM function are components of the same network element.

The subject matter described herein for methods, systems, and computer program products for providing fault-tolerant service interaction and mediation function in a communications network may be implemented in hardware, software, firmware, or any combination thereof. As such, the terms “function” or “module” as used herein refer to hardware, software, and/or firmware for implementing the feature being described. In one exemplary implementation, the subject matter described herein may be implemented using a computer program product comprising computer executable instructions embodied in a computer readable medium. Exemplary computer readable media suitable for implementing the subject matter described herein include disk memory devices, chip memory devices, programmable logic devices, and application specific integrated circuits. In addition, a computer program product that implements the subject matter described herein may be located on a single device or computing platform or may be distributed across multiple devices or computing platforms.

### BRIEF DESCRIPTION OF THE DRAWINGS

Preferred embodiments of the subject matter described herein will now be explained with reference to the accompanying drawings of which:

FIG. 1 is a flow chart illustrating an exemplary method for providing fault-tolerant service capability interaction management capability in accordance with an embodiment of the subject matter described herein;

FIG. 2 is a block diagram illustrating an exemplary fault-tolerant service capability interaction management system in accordance with an embodiment of the subject matter described herein; and

FIG. 3 is a block diagram illustrating an exemplary fault-tolerant service capability interaction manager network element in accordance with an embodiment of the subject matter described herein.

### DETAILED DESCRIPTION

In accordance with the subject matter disclosed herein, methods, systems, and computer program products for providing fault-tolerant service interaction and mediation in a communications network are provided. Service interaction refers to the process of managing interactions between network entities that request and use network services, commonly referred to as service clients, and network entities that provide network services, commonly referred to as application servers. Service mediation refers to the conversion of messages from one message protocol into another message protocol. Service mediation may also entail determining whether a requesting client or communications service subscriber is authorized to access network applications/services, and subsequently enforcing such access authorization rules.

One implementation of a system for providing enhanced service interaction and mediation is disclosed in U.S. Provisional Patent Application Ser. No. 60/925,612, filed Apr. 20, 2007, and U.S. Provisional Patent Application Ser. No. 60/991,260, filed Nov. 30, 2007, the disclosures of which are incorporated by reference herein in their entireties. The above-referenced U.S. Provisional Patent Applications disclose an enhanced service capability interaction manager for performing service interaction and mediation. The enhanced SCIM extends the functionality of the SCIM as defined by 3GPP by adding the capability to generate SCIM-to-server messages to multiple application servers in response to receiving a single client-to-SCIM message from a service client, and by adding the capability to aggregate server-to-SCIM messages received from multiple application servers in response to the service queries and send the aggregated response as a SCIM-to-client message to the service client.

To increase the reliability of a communications network, components of the network may be configured in an active/standby configuration, in which one instance of a particular component, such as a service capability interaction manager function, operates in active mode while a redundant instance of that component operates in a standby mode, ready to assume the functions of the active component in the event that the active component should fail or otherwise be deactivated.

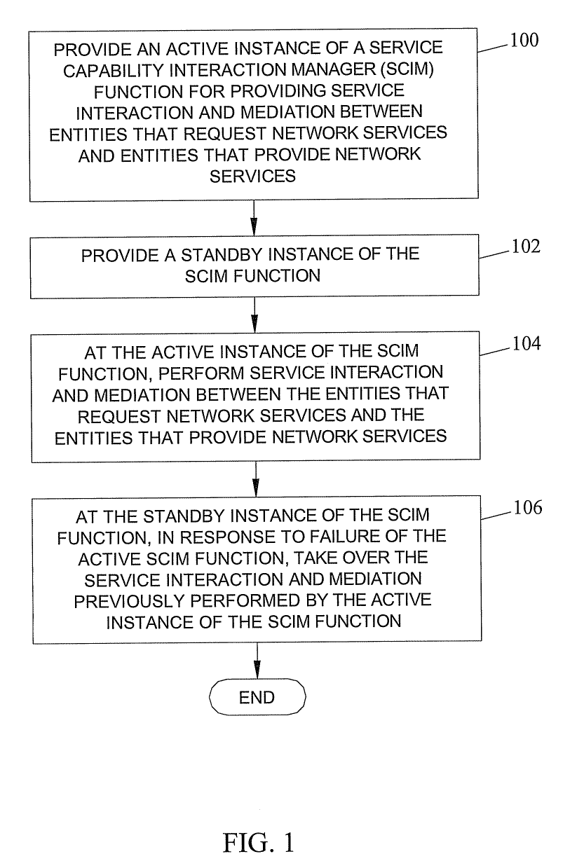

FIG. 1 is a flow chart illustrating an exemplary method of providing fault-tolerant service interaction and mediation capability in accordance with an embodiment of the subject matter described herein.

At block 100, an active instance of a service capability interaction manager (SCIM) function is provided. At block 102, a standby instance of the SCIM function is provided. At block 104, the active instance of the SCIM function performs service interaction and mediation between the entities that request network services and the entities that provide network services. At block 106, in response to failure of the active SCIM function, the standby instance of the SCIM function takes over the service interaction and mediation previously performed by the active instance of the SCIM function.

In one embodiment, if a failed instance of the SCIM function is restored and resumes operation, the restored instance of the SCIM function may automatically re-synchronize itself with the currently active instance of the SCIM function. The restored instance of the SCIM function may continue operation as the new standby instance of the SCIM function while the former standby instance of the SCIM function continues as the active instance of the SCIM function. Alternatively, the current active instance of the SCIM function may return to its role as standby instance of the SCIM function, while the restored instance of the SCIM function returns to its role as active instance of the SCIM function.

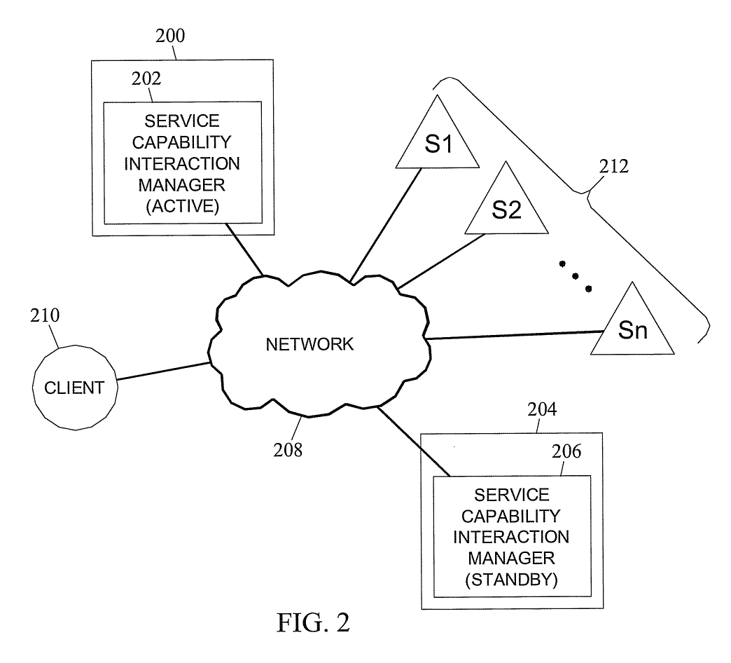

FIG. 2 is a block diagram illustrating an exemplary fault-tolerant service interaction and mediation system in accordance with an embodiment of the subject matter described herein.

In one embodiment, the system may include a first, active network element 200 including an active instance of a service capability interaction manager 202 for providing service interaction and mediation between entities that request network services and entities that provide network services, and a second, standby network element 204 including a standby instance of the service capability interaction manager 206. For example, communications network 208 may contain a service client 210, such as a mobile switching center (MSC) or a service switching point (SSP), which may request a network service, and one or more application servers 212, such as a service control point (SCP), a session initiation protocol (SIP) application server (SAS), an extensible markup language (XML) application server, or a simple object access protocol (SOAP) server, which provide network services.

In one embodiment, active network element 200 and standby network element 204 may be configured as a redundant pair in an 1-active/1-standby configuration. For example, active network element 200 may be in active mode while standby network element 204 may be in standby mode. Alternative embodiments may include a 1-active/N-standby configuration, in which one network element may be active while N number of network elements may be in standby mode; an M-active/N-standby configuration, in which M number of network elements may be active while N number of network elements may be in standby mode; and an M-active/1-standby configuration, in which M number of network elements may be in active mode while one network element may be in standby mode.

In embodiments that include multiple standby network elements, the standby network elements may arbitrate among themselves to determine which standby network element will become active. For example, each standby network element may be programmed with values that indicate each network element's relative priority, in which case the network element with the highest relative priority may become the next active network element. Example priority schemes include fixed priority, round-robin priority, or other priority metric. In alternative embodiments, an entity in the communications network other than the standby network elements may select which standby network element will become active. For example, the active network element itself may be capable of detecting its own failure, and, in response initiating or performing the failover sequence. Alternatively, an entity other than the active and standby network elements may monitor the health of at least the currently active network element and select which standby network element will become active in response to a failover condition.

In one embodiment, the active and standby network elements may be co-located. For example, the active and standby instances of the SCIM function may be duplicate hardware and/or software components in a system, such as duplicated hardware on one circuit board or card; the two instances may be physically separate cards, servers, or other discrete entity within a rack; the two instances may be components within separate racks; or other configurations known in the art to provide functional redundancy.

In an alternative embodiment, active network element 200 is geographically diverse from standby network element 204, such that operation of standby instance of the service capability interaction manager 206 is geographically isolated from a failure of active instance of a service capability interaction manager 202. By locating active network element 200 and standby network element 204 in geographically diverse locations, a site failure at the geographic location of one network element is unlikely to affect the other network element located in a different geographic location, improving the fault-tolerance of network 208 to site failures.

In some embodiments, active network element 200 and/or standby network element 204 may contain additional functions other than active instance of a service capability interaction manager 202 and standby instance of the service capability interaction manager 206, respectively, but for simplicity, the term active network element 200 will hereinafter be used to mean “active network element 200 or a component within it, such as active instance of a service capability interaction manager 202”, and the term “standby network element 204” will hereinafter be used to mean “standby network element 204 or a component within it, such as standby instance of the service capability interaction manager 206”.

In one embodiment, in the event of a failure in active network element 200, the failover process by which standby network element 204 switches from the standby state to an active state may be manual—i.e., requiring human intervention. In an alternative embodiment, the failover process may be automatic. For example, some component within network 208 may detect a failure in active network element 200 and initiate a failover sequence whereby standby network element 204 switches to an active state.

In one embodiment, standby network element 204 is used to detect a failure in active network element 200. Upon detection of the failure of active network element 200, standby network element 204 switches to an active state. For example, standby network element 204 may monitor the status of active instance of a service capability interaction manager 202 to detect a failure in active instance of a service capability interaction manager 202 and take appropriate action should such a failure occur.

An entity or component of the communications network other than standby network element 204 may detect the failure in active network element 200. In one embodiment, network 208 may include a separate component for detecting a failure at active network element 200, for switching standby network element 204 into active mode, and for switching the failed active network element 200 into a non-active state if necessary. In another embodiment, active network element 200 may be capable of detecting its own failure and, in response, initiate or perform the failover sequence.

In one embodiment, detection of a partial failure in active network element 200 may trigger a process which not only switches standby network element 204 to an active state, but also switches the partially functioning active network element 200 to a non-active state. For example, in the case of a partial failure of active network element 200, active network element 200 may continue to operate at less than full capabilities. In one embodiment, a partially functioning SCIM may be configured to continue operating—despite the partial failure—until it is explicitly instructed to change from an active state to a non-active state. In such an embodiment, upon detection of a partial failure of active network element 200, it may be necessary to explicitly instruct active network element 200 to switch off, disconnect or otherwise isolate itself from the communications network, put itself into a maintenance or debugging mode, and the like.

Redirection of network traffic from a failed active network element 200 to standby network element 204 that has been switched into an active mode may be performed using a variety of selection mechanisms. In one embodiment, the selection mechanism may be a hardware connection, such as a switch. In an alternative embodiment, the selection mechanism may utilize a virtual IP address (VIP) to represent both the active and standby network elements. In such embodiments, communications addressed to the virtual IP address are received by both the active and standby network elements, but the network elements may be configured such that only the currently active network element will respond. For example, messages addressed to the VIP associated with the network SCIM function will may received by both active network element 200 and standby network element 204, but only active network element 200 will respond. Upon a failure of active network element 200 and the subsequent failover process, during which standby network element 204 becomes active and the failed active network element 200 becomes non-active, standby network element 204 may be reconfigured so that it will respond to communications addressed to the virtual IP address. In this manner, devices on the network continue to communicate with the same virtual IP address. From their perspective, nothing has changed, and it is not necessary to update or remap the address for the network SCIM function.

In alternative embodiments, the selection mechanism may include remapping an identifier associated with an instance of the SCIM function. In one embodiment, a universal resource identifier (URI) associated with the SCIM function may be remapped from the IP address of active network element 200 to the IP address of standby network element 204. For example, a DNS entry corresponding to the network SCIM function may be updated so that a DNS query returns the address of whichever network element is currently active.

In one embodiment, a signaling protocol for monitoring and exchanging state information between active network element 200 and standby network element 204 is used to detect the failure of active network element 200.

In one embodiment, active network element 200 may continually update standby network element 204 with information such that in the event of a failover, standby network element 204 has enough information to begin performance of the SCIM function with little or no delay. For example, active network element 200 may continually update standby network element 204 regarding call state information for all calls being currently processed by active instance of a service capability interaction manager 202.

In another embodiment, standby network element 204 may continually or periodically request status updates from the active SCIM function. Example queries may range from the simple, such as an “Are you still alive?” query, to the complex, such as a request for database synchronization between the active and standby instances.

In one embodiment, the signaling protocol used to detect the failure of active network element 200 includes communicating heartbeat messages between the active and standby instances of the SCIM function, such as used by the Linux high availability (HA) protocol. For example, if active network element 200 fails to send a heartbeat message to standby network element 204 before a heartbeat interval timer expires, standby network element 204 assumes that the active instance has failed or otherwise become inoperative, and the standby instance switches itself to an active state.

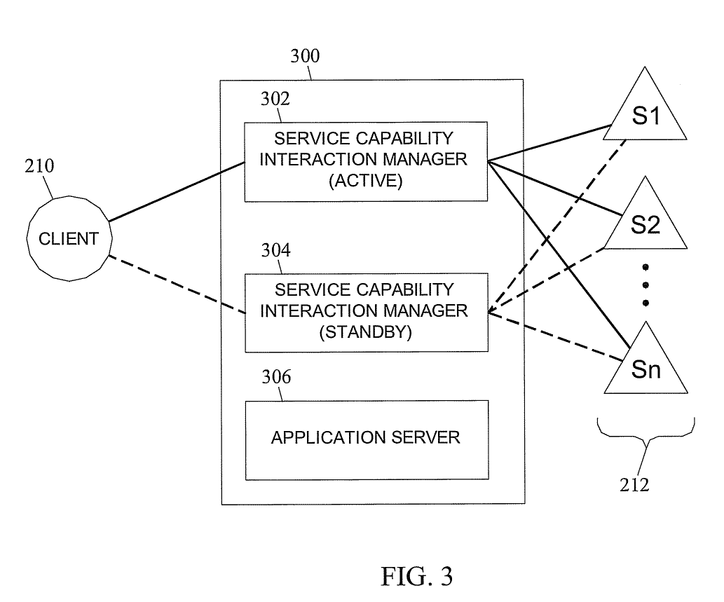

As stated above, a network element is a logical grouping of entities that perform a specific assigned function or group of functions within a communications network. Thus, a network element need not be limited to containing only one instance of a function, but may contain multiple instances of the same function. Furthermore, a group of entities that comprise a network element need not be limited to one geographic location. Components of the network element may be located in more than one geographic location, yet still collectively perform their logical function or functions. While FIG. 2 illustrates implementation of redundancy at a network element level (i.e., redundant network elements), FIG. 3 illustrates an implementation of redundancy at a sub-network element level (i.e., redundant functions within a single network element).

FIG. 3 is a block diagram illustrating an exemplary fault-tolerant service interaction and mediation network element in accordance with an embodiment of the subject matter described herein.

In one embodiment, fault-tolerant service interaction and mediation network element 300 may include an active instance of a SCIM function 302 for providing service interaction and mediation between entities that request network services and entities that provide network services, and a standby instance of a SCIM function 304. For example, network element 300 may provide service interaction and mediation between service client 210, such as an MSC, SSP, or other requesters of network services, and application servers 212, such as SCPs, SASs, or other providers of network services.

In one embodiment, active instance of a SCIM function 302 and standby instance of a SCIM function 304 may be configured as a redundant pair in an 1-active/1-standby configuration. For example, active instance of a SCIM function 302 may be in active mode while standby instance of a SCIM function 304 may be in standby mode. Alternative embodiments may include a 1-active/N-standby configuration, in which one instance of a SCIM function may be active while N number of instances of a SCIM function may be in standby mode; an M-active/N-standby configuration, in which M number of instances of a SCIM function may be active while N number of instances of a SCIM function may be in standby mode; and an M-active/1-standby configuration, in which M number of instances of a SCIM function may be in active mode while one instance of a SCIM function may be in standby mode.

In embodiments that include multiple standby instances of a SCIM function, the standby instances of a SCIM function may arbitrate among themselves to determine which standby instance of a SCIM function will become active. For example, each standby instance of a SCIM function may be programmed with values that indicate each instance of a SCIM function's relative priority, in which case the instance of a SCIM function with the highest relative priority may become the next active instance of a SCIM function. Example priority schemes include fixed priority, round-robin priority, or other priority metric. In alternative embodiments, an entity in the communications network other than the standby instances of a SCIM function may select which standby instance of a SCIM function will become active. For example, the active instance of a SCIM function itself may be capable of detecting its own failure, and, in response initiating or performing the failover sequence. Alternatively, an entity other than the active and standby instances of a SCIM function may monitor the health of at least the currently active instance of a SCIM function and select which standby instance of a SCIM function will become active in response to a failover condition.

In one embodiment, the active and standby instances of a SCIM function may be co-located. For example, active instance of a SCIM function 302 and standby instance of a SCIM function 304 may be physical cards in a network rack, servers in a site, and so on. In such embodiments, failover may involve switching at a functional level, rather than at the network element level—e.g., switching out a failed sub-unit of network element 300, such as from active instance of a SCIM function 302 to standby instance of a SCIM function 304, rather than switching out network element 300 entirely. In this manner, overhead associated with failover, such as data backup, data or state synchronization, and so on, may be avoided with regard to other components that may be contained within network element 300.

In an alternative embodiment, active instance of a SCIM function 302 is geographically diverse from standby instance of a SCIM function 304, such that operation of standby instance of a SCIM function 304 is geographically isolated from a failure of active instance of a SCIM function 302. By locating active instance of a SCIM function 302 and standby instance of a SCIM function 304 in geographically diverse locations, a site failure at the geographic location of one instance of a SCIM function is unlikely to affect the other instance of a SCIM function located in a different geographic location, improving the fault-tolerance of network element 300 to site failures.

In one embodiment, in the event of a failure in active instance of a SCIM function 302, the failover process by which standby instance of a SCIM function 304 switches from the standby state to an active state may be manual—i.e., requiring human intervention. In an alternative embodiment, the failover process may be automatic. For example, some component within network element 300 may detect a failure in active instance of a SCIM function 302 and initiate a failover sequence whereby standby instance of a SCIM function 304 switches to an active state.

In one embodiment, standby instance of a SCIM function 304 is used to detect a failure in active instance of a SCIM function 302. Upon detection of the failure of active instance of a SCIM function 302, standby instance of a SCIM function 304 switches to an active state. For example, standby instance of a SCIM function 304 may monitor the status of active instance of a SCIM function 302 to detect a failure in active instance of a SCIM function 302 and take appropriate action should such a failure occur.

An entity or component of network element 300 other than standby instance of a SCIM function 304 may detect the failure in active instance of a SCIM function 302. In one embodiment, network element 300 may include a separate component for detecting a failure at active instance of a SCIM function 302, for switching standby instance of a SCIM function 304 into active mode, and for switching the failed active instance of a SCIM function 302 into a non-active state if necessary. In another embodiment, active instance of a SCIM function 302 may be capable of detecting its own failure and, in response, initiate or perform the failover sequence.

In one embodiment, detection of a partial failure in active instance of a SCIM function 302 may trigger a process which not only switches standby instance of a SCIM function 304 to an active state, but also switches the partially functioning active instance of a SCIM function 302 to a non-active state. For example, in the case of a partial failure of active instance of a SCIM function 302, active instance of a SCIM function 302 may continue to operate at less than full capabilities. In one embodiment, a partially functioning SCIM function may be configured to continue operating—despite the partial failure—until it is explicitly instructed to change from an active state to a non-active state. In such an embodiment, upon detection of a partial failure of active instance of a SCIM function 302, it may be necessary to explicitly instruct active instance of a SCIM function 302 to switch off, disconnect or otherwise isolate itself from the communications network, put itself into a maintenance or debugging mode, and the like.

Redirection of network traffic from a failed active instance of a SCIM function 302 to standby instance of a SCIM function 304 that has been switched into an active mode may be performed using a variety of selection mechanisms. In one embodiment, the selection mechanism may be a hardware connection, such as a switch. In an alternative embodiment, the selection mechanism may utilize a virtual IP address (VIP) to represent both the active and standby instances of a SCIM function. In such embodiments, communications addressed to the virtual IP address are received by both the active and standby instances of a SCIM function, but the instances of a SCIM function may be configured such that only the currently active instance of a SCIM function will respond. For example, messages addressed to the VIP associated with the network SCIM function will may received by both active instance of a SCIM function 302 and standby instance of a SCIM function 304, but only active instance of a SCIM function 302 will respond. Upon a failure of active instance of a SCIM function 302 and the subsequent failover process, during which standby instance of a SCIM function 304 becomes active and the failed active instance of a SCIM function 302 becomes non-active, standby instance of a SCIM function 304 may be reconfigured so that it will respond to communications addressed to the virtual IP address. In this manner, devices on the network continue to communicate with the same virtual IP address. From their perspective, nothing has changed, and it is not necessary to update or remap the address for the network SCIM function.

In alternative embodiments, the selection mechanism may include remapping an identifier associated with an instance of the SCIM function. In one embodiment, a universal resource identifier (URI) associated with the SCIM function may be remapped from the IP address of active instance of a SCIM function 302 to the IP address of standby instance of a SCIM function 304. For example, a DNS entry corresponding to the network SCIM function may be updated so that a DNS query returns the address of whichever instance of a SCIM function is currently active.

In one embodiment, a signaling protocol for monitoring and exchanging state information between active instance of a SCIM function 302 and standby instance of a SCIM function 304 is used to detect the failure of active instance of a SCIM function 302.

In one embodiment, active instance of a SCIM function 302 may continually update standby instance of a SCIM function 304 with information such that in the event of a failover, standby instance of a SCIM function 304 has enough information to begin performance of the SCIM function with little or no delay. For example, active instance of a SCIM function 302 may continually update standby instance of a SCIM function 304 regarding call state information for all calls being currently processed by active instance of a SCIM function 302.

In another embodiment, standby instance of a SCIM function 304 may continually or periodically request status updates from active instance of a SCIM function 302. Example queries may range from the simple, such as an “Are you still alive?” query, to the complex, such as a request for database synchronization between the active and standby instances.

In one embodiment, the signaling protocol used to detect the failure of active instance of a SCIM function 302 includes communicating heartbeat messages between the active and standby instances of the SCIM function, such as used by the Linux high availability (HA) protocol. For example, if active instance of a SCIM function 302 fails to send a heartbeat message to standby instance of a SCIM function 304 before a heartbeat interval timer expires, standby instance of a SCIM function 304 assumes that active instance of a SCIM function 302 has failed or otherwise become inoperative, and standby instance of a SCIM function 304 switches itself to an active state.

Since the purpose of a SCIM function is to mediate between service clients and application servers, the SCIM may often receive service requests or database queries from the service client. For example, a SCIM that communicates with an MSC that serves a large population of prepaid mobile subscribers may issue a large number of queries to a prepaid SCP, such as to verify, for each IDP received from the MSC, that the calling and/or called party has a sufficient prepaid account balance to allow the call to proceed. Such a SCIM might benefit from a close association with the prepaid SCP function. Thus, an instance of a SCIM function may be co-located with a non-SCIM function, such as an application server function, database function, and the like. Co-location may provide benefits such as a reduction of network traffic, since the query/response messages may remain internal to the network entity containing the SCIM and non-SCI M functions, and faster response time, due to the elimination of round-trip delay to a remote SCP and the potential elimination of the requirement of protocol conversion.

In one embodiment, network element 300 may also include a service control network entity, such as an application server 306, for providing a network service. Examples of network service functions that may be co-located with a SCIM function include a number portability (NP) function, a local number portability (LNP) function, a mobile number portability (MNP) function, a toll-free service function, an 800-number service function, an E.164 numbering (ENUM) function, a prepaid subscriber function, a calling name delivery (CNAM) function, a presence function, a home location register (HLR) function, a visitor location register (VLR) function, a home subscriber server (HSS) function, an authentication, authorization, and accounting (AAA) function, a session initiation protocol application server (SAS) function, a push-to-talk function, a short code dialing function, a virtual private network (VPN) function, a ringback tones function, a voice mail server function, a message server function, a presence server function, a service control point (SCP) function, a location-based services function, such as one based on either a wireless infrastructure or on the global positioning system (GPS), and other functions, such as a database function.

In one embodiment, the non-SCIM function co-located with a SCIM function may be in a redundant configuration, such as in one of the active/standby configurations described above. For example, network element 300 may include both an active and a standby instance of application server 306. In one embodiment, the redundant non-SCIM functions may be geographically diverse for improved fault-tolerance against site failures. For example, the active and standby instances of application server 306 may be located in separate geographic locations.

It will be understood that various details of the presently disclosed subject matter may be changed without departing from the scope of the presently disclosed subject matter. Furthermore, the foregoing description is for the purpose of illustration only, and not for the purpose of limitation.

What is claimed is:

1. A method for providing fault-tolerant service interaction and mediation capability, the method comprising:
providing an active instance of a service capability interaction manager (SCIM) function for providing, in a communications network, service interaction and mediation between entities that request network services and entities that provide network services;
providing a standby instance of the SCIM function;
at the active instance of the SCIM function, performing service interaction and mediation between the entities that request network services and the entities that provide network services; and
at the standby instance of the SCIM function, in response to failure of the active instance of the SCIM function, taking over the service interaction and mediation previously performed by the active instance of the SCIM function.

2. The method of claim 1 wherein providing the active instance of the SCIM function includes locating the active instance of the SCIM function in a first geographic location, wherein providing the standby instance of the SCIM function includes locating the standby instance of the SCIM function in a second geographic location different from the first geographic location, and wherein operation of the standby instance of the SCIM function is geographically isolated from a failure of the active instance of the SCIM function.

3. The method of claim 1 comprising using one of the active instance of the SCIM function, the standby instance of the SCIM function, and an entity separate from the active and standby instances of the SCIM function for detecting failure of the active instance of the SCIM function, and, in response to detecting the failure, alerting the standby instance of the SCIM function of the failure.

4. The method of claim 3 wherein detecting failure of the active instance of the SCIM function includes using a signaling protocol for monitoring and exchanging state information between the active and standby instances of the SCIM function.

5. The method of claim 4 wherein using the signaling protocol includes communicating heartbeat messages between the active and standby instances of the SCIM function.

6. The method of claim 1 wherein performing service interaction and mediation includes at least one of:
receiving service requests from the entities that request the network services and formulating mediated requests to the entities that provide the network services; and
receiving responses to the service requests from the entities that provide the network services and aggregating the responses.

7. The method of claim 1 comprising detecting that the failed instance of the SCIM function has been restored to correct operation, and, in response to detecting that the failed instance of the SCIM function has been restored to correct operation, automatically re-synchronizing the restored instance of the SCIM function with the current active instance of the SCIM function.

8. A fault-tolerant service interaction and mediation system, comprising:
a first network element including an active instance of a service capability interaction manager (SCIM) function for performing service interaction and mediation between entities that request network services and entities that provide network services; and
a second network element including a standby instance of the SCIM function for, in response to failure of the active instance of the SCIM function, taking over the service interaction and mediation previously performed by the active instance of the SCIM function.

9. The system of claim 8 wherein at least one of the active instance of the SCIM function, the standby instance of the SCIM function, and an entity separate from the active and standby instances of the SCIM function is adapted to detect the restoration of the failed instance of the SCIM function to correct operation, and, in response to detecting the restoration of the failed instance of the SCIM function to correct operation, automatically re-synchronize the restored instance of the SCIM function with the current active instance of the SCIM function.

10. The system of claim 8 wherein the active instance of the SCIM function is located in a first geographic location, wherein the standby instance of the SCIM function is located in a second geographic location different from the first geographic location, and wherein operation of the standby instance of the SCIM function is geographically isolated from a failure of the active instance of the SCIM function.

11. The system of claim 8 wherein at least one of the active instance of the SCIM function, the standby instance of the SCIM function, and an entity separate from the active and standby instances of the SCIM function is adapted to detect failure of the active instance of the SCIM function, and, in response to detecting the failure, alert the standby instance of the SCIM function of the failure.

12. The system of claim 11 wherein detecting the failure of the active instance of the SCIM function includes using a signaling protocol for monitoring and exchanging state information between the active and standby instances of the SCIM function.

13. The system of claim 12 wherein the signaling protocol comprises a heartbeat message communicated between the active and standby instances of the SCIM function.

14. The system of claim 8 wherein performing service interaction and mediation includes at least one of:
receiving service requests from the entities that request the network services and formulating mediated requests to the entities that provide the network services; and
receiving responses to the service requests from the entities that provide the network services and aggregating the responses.

15. A fault-tolerant service interaction and mediation network element, comprising:
an active instance of a service capability interaction manager (SCIM) function for performing service interaction and mediation between entities that request network services and entities that provide network services; and
a standby instance of the SCIM function for, in response to failure of the active instance of the SCIM function, taking over the service interaction and mediation previously performed by the active instance of the SCIM function;
wherein the active and standby instances of the SCIM function are components of the same network element.

16. The network element of claim 15 wherein the active instance of the SCIM function is located in a first geographic location, wherein the standby instance of the SCIM function is located in a second geographic location different from the first geographic location, and wherein operation of the standby instance of the SCIM function is geographically isolated from a failure of the active instance of the SCIM function.

17. The network element of claim 15 wherein at least one of the active instance of the SCIM function, the standby instance of the SCIM function, and an entity separate from the active and standby instances of the SCIM function is adapted to detect failure of the active instance of the SCIM function, and, in response to detecting the failure, alert the standby instance of the SCIM function of the failure.

18. The network element of claim 17 wherein detecting failure of the active instance of the SCIM function includes using a signaling protocol for monitoring and exchanging state information between the active and standby instances of the SCIM function.

19. The network element of claim 18 wherein the signaling protocol comprises a heartbeat message communicated between the active and standby instances of the SCIM function.

20. The network element of claim 15 wherein performing service interaction and mediation includes at least one of:
receiving service requests from the entities that request the network services and formulating mediated requests to the entities that provide the network services; and
receiving responses to the service requests from the entities that provide the network services and aggregating the responses.

21. A service capability interaction management network element, comprising:
a service capability interaction manager (SCIM) function for providing, in a communications network, service interaction and mediation between entities that request network services and entities that provide network services; and
a service control network entity for providing a network service.

22. The network element of claim 21 wherein the network service provided by the service control network entity includes at least one of a number portability (NP) function, a local number portability (LNP) function, a mobile number portability (MNP) function, a toll-free service function, an 800-number service function, an E.164 numbering (ENUM) function, a prepaid subscriber function, a calling name delivery (CNAM) function, a presence function, a home location register (HLR) function, a visitor location register (VLR) function, a home subscriber server (HSS) function, an authentication, authorization, and accounting (AAA) function, a session initiation protocol application server (SAS) function, a push-to-talk function, a short code dialing function, a virtual private network (VPN) function, a ringback tones function, a least cost routing function, a TDM-to-packet network offload function, a voice mail server function, a message server function, a presence server function, a service control point (SCP) function, a location-based services function, and a database function.

23. A computer program product comprising computer-executable instructions embodied in a computer-readable medium for performing steps comprising:
providing an active instance of a SCIM function for providing, in a communications network, service interaction and mediation between entities that request network services and entities that provide network services;
providing a standby instance of the SCIM function;
at the active instance of the SCIM function, performing service interaction and mediation between the entities that request network services and the entities that provide network services; and
at the standby instance of the SCIM function, in response to failure of the active SCIM function, taking over the service interaction and mediation previously performed by the active instance of the SCIM function.

24. The computer program product of claim 23 wherein the active instance of the SCIM function is located in a first geographic location, wherein the standby instance of the SCIM function is located in a second geographic location different from the first geographic location, and wherein operation of the standby instance of the SCIM function is geographically isolated from a failure of the active instance of the SCIM function.

25. The computer program product of claim 23 comprising using one of the active instance of the SCIM function, the standby instance of the SCIM function, and an entity separate from the active and standby instances of the SCIM function for detecting failure of the active instance of the SCIM function, and, in response to detecting the failure, alerting the standby instance of the SCIM function of the failure.
